(19) United States
(12) Patent Application Publication
(10) Pub. No.: US 2009/0215269 A1
(43) Pub. Date: Aug. 27, 2009

(54) INTEGRATED CHEMICAL MECHANICAL POLISHING COMPOSITION AND PROCESS FOR SINGLE PLATEN PROCESSING

(75) Inventors: Karl E. Boggs, Hopewell Junction, NY (US); Michael S. Darsillo, Landenberg, PA (US); Peter Wrschka, Tempo, AZ (US); James Welch, Clayton, NC (US); Jeffrey Giles, Raleigh, NC (US); Michele Stawasz, New Milford, CT (US)

Correspondence Address: MOORE & VAN ALLEN PLLC, P.O. BOX 13706, Research Triangle Park, NC, 27709, US

(73) Assignee: Advanced Technology Materials Inc., Danbury, CT (US)

(21) Appl. No.: 11/916,727

(22) PCT Filed: Jun. 6, 2006
(86) PCT No.: PCT/US06/22037

§ 371 Date: Oct. 13, 2008

Related U.S. Application Data
(60) Provisional application No. 60/687,721, filed on Jun. 6, 2005.

(51) Int. Cl. H01L 21/306; C09K 13/00

(52) U.S. Cl. 438/693; 438/692; 252/79.1; 257/E21.23

(57) ABSTRACT

Chemical mechanical polishing (CMP) compositions and single CMP platen process for the removal of copper and barrier layer material from a microelectronic device substrate having same thereon. The process includes the in situ transformation of a Step I slurry formulation, which is used to selectively remove and planarize copper, into a Step II slurry formulation, which is used to selectively remove barrier layer material, on a single CMP platen pad.

### FIELD OF THE INVENTION

The present invention relates to chemical mechanical polishing compositions and process for the single platen polishing of semiconductor substrates having copper patterns, e.g., copper interconnects, electrodes, or other device metallization, which can include a barrier layer material as part of the structure thereon.

### DESCRIPTION OF THE RELATED ART

Copper is employed in semiconductor manufacturing as a material of construction for components of semiconductor device structures (e.g., wiring, electrodes, bond pads, conductive vias, contacts, field emitter base layers, etc.) on wafer substrates, and it is rapidly becoming the interconnect metal of choice in semiconductor manufacturing due to its higher conductivity and increased electromigration resistance relative to aluminum and aluminum alloys.

Typically, the process scheme for incorporating copper in semiconductor manufacturing involves the damascene approach, wherein features are etched in a dielectric material, filled in with blanket metallization, and removal of the surface metallization to isolate the features. In the dual damascene process a single fill is used to form both plugs and lines. Since copper has a propensity to diffuse into the dielectric material, leading to leakage between metal lines and migration into the transitor structure changing the electronic properties, barrier/liner layers, such as Ta and/or TaN deposited by various deposition methods, are often used to seal the copper interconnects. Following deposition of the barrier layer material, a thin seed layer of copper is deposited on the liner material via physical or chemical vapor deposition, followed by electrodeposition of copper to fill the features.

As copper is deposited to fill the etched features, elevational disparity or topography develops across the surface of the layer, having raised and recessed regions. The deposited copper overburden and the barrier material in the up areas must then be removed to electrically isolate the individual features of the circuitry and to render it of suitable form to accommodate subsequent process steps in the fabrication of the finished semiconductor product, and in order to satisfactorily operate in the micro-circuitry in which it is present. The planarization typically involves chemical mechanical polishing (CMP), using a CMP composition formulated for such purpose.

Chemical mechanical polishing or planarization is a process in which material is removed from a surface of a semiconductor wafer, and the surface is polished (planarized) by coupling a physical process such as abrasion with a chemical process such as oxidation or chelation. In its most rudimentary form, CMP involves applying slurry, specifically a solution of an abrasive and an active chemistry, to a wafer surface or polishing pad that polishes the different materials on the surface structure of the semiconductor wafer to achieve both the removal of unwanted material and planarization of the wafer surface. It is not desirable for the removal or polishing process to be purely physical or purely chemical, but rather the synergistic combination of both is preferred in order to achieve fast, uniform removal and a planar surface of the materials of construction.

Due to the difference in chemical reactivity between copper and the barrier layer, e.g. Ta and/or TaN, two chemically and mechanically distinct slurries are often used in the copper CMP process. The Step I slurry is used to rapidly planarize the topography and to uniformly remove the copper, with the Step I polish stopping at the barrier layer. Typically the ratio of copper removal rate to barrier layer removal rate during Step I is greater than 100:1. The Step II slurry removes the barrier layer material at a high removal rate and stops in or at the dielectric layer, or alternatively stops in or at a cap layer that has been applied to protect the dielectric. Typically, the ratio of barrier layer removal rate to copper removal rate during Step II is selected based on integration requirements.

Step I and Step II slurry compositions are typically incompatible for use on the same platen during CMP processing due to factors such as pH shock, incompatibility between chemical constituents and/or abrasives, and other problems that degrade polish performance or cause defectivity problems. For example, generally, Step I slurries include alumina, which is cationic, and Step II slurries include silica, which is anionic. Accordingly, conventional CMP processes include copper removal using the Step I slurry on one or more platens followed by transference of the substrate to another platen for barrier layer material removal using the Step II slurry.

There remains a need for compositions and a process for chemically mechanically polishing a microelectronic device substrate including copper and barrier layer material on a single platen, whereby the Step I polishing composition and process and the Step II polishing composition and process are performed on the same platen, i.e., without transference of the microelectronic device substrate to a second platen for Step II processing thereon. The single platen composition and process should maximize planarization efficiency, uniformity and removal rate while concomitantly minimizing surface imperfections, such as dishing and erosion, and damage to underlying topography.

### SUMMARY OF THE INVENTION

The present invention relates to chemical mechanical polishing compositions and process for the polishing of microelectronic device substrates having copper and barrier layer material thereon. Specifically, the present invention relates to the composition and polishing process of a Step I and a Step II CMP process on a single platen, i.e., without transference of the microelectronic device substrate to a second platen for Step II processing.

In one aspect, the invention relates to a CMP slurry composition comprising at least one passivating agent, at least one solvent, at least one abrasive, and optionally at least one pH adjustment agent, wherein said composition is further characterized by comprising at least one of the following components (I) or (II):
(I) at least one oxidizing agent and at least one chelating agent, wherein said composition is useful for removing and planarizing copper; or
(II) at least one barrier layer removal enhancer, at least one selectivity additive, and optionally at least one oxidizing agent, wherein said composition is useful for the selective removal and polishing of barrier layer material.

In another aspect, the invention relates to a CMP slurry composition consisting essentially of at least one passivating agent, at least one solvent, at least one abrasive, at least one oxidizing agent, at least one chelating agent and optionally at least one pH adjustment agent, wherein the CMP slurry composition is useful for removing and planarizing copper.

In still another aspect, the invention relates to a CMP slurry composition comprising at least one passivating agent, at least one solvent, at least one abrasive, at least one chelating agent, at least one barrier layer removal enhancer, at least one selectivity additive, and optionally at least one oxidizing agent, optionally at least one pH adjustment agent, wherein the CMP slurry composition is useful for the selective removal and polishing of barrier layer material.

In yet another aspect, the invention relates to a method of polishing a wafer substrate having copper and barrier layer material deposited thereon at a platen, said method comprising:
contacting the microelectronic device substrate having copper thereon on the platen for sufficient time and under first chemical mechanical polishing (CMP) conditions with a first CMP slurry composition to substantially remove copper from the microelectronic device substrate and expose barrier layer material, wherein the first CMP slurry composition comprises at least one oxidizing agent, at least one passivating agent, at least one chelating agent, solvent, and at least one acid-stable abrasive; and
contacting the microelectronic device substrate having barrier layer material thereon on the same platen for sufficient time and under second CMP conditions with a second CMP slurry composition to remove at least a portion of the barrier layer material from the microelectronic device substrate, wherein the second CMP slurry composition comprises at least one oxidizing agent, at least one passivating agent, at least one chelating agent, at least one solvent, and at least one acid-stable abrasive,
with the proviso that the first and second CMP slurry compositions are devoid of persulfate and phosphorous acid and/or a salt thereof.

In a further aspect, the present invention relates to a kit comprising, in one or more containers, Step I CMP slurry composition reagents, wherein the Step I CMP slurry composition comprises at least one passivating agent, at least one oxidizing agent, at least one chelating agent, at least one solvent, at least one acid-stable abrasive, and optionally at least one pH adjustment agent, and wherein one or more additional components suitable for combination with the Step I CMP slurry to form a Step II CMP slurry are optionally included in one or more containers, wherein the one or more additional components are selected from the group consisting of at least one barrier layer removal enhancer, at least one selectivity enhancer, and combinations thereof.

In another aspect, the present invention relates to a method of manufacturing a microelectronic device, said method comprising contacting the microelectronic device substrate having copper thereon for sufficient time and under chemical mechanical polishing (CMP) conditions with a CMP slurry composition to remove copper from the microelectronic device substrate, wherein the CMP slurry composition comprises at least one oxidizing agent, at least one passivating agent, at least one chelating agent, at least one solvent, and at least one acid-stable abrasive, and optionally, incorporating the microelectronic device into a product, with the proviso that the CMP slurry composition is devoid of persulfate and phosphorous acid and/or a salt thereof.

In a further aspect, the present invention relates to a method of manufacturing a microelectronic device, said method comprising contacting the microelectronic device substrate having barrier layer material thereon for sufficient time and under CMP conditions with a CMP slurry composition to remove barrier layer material from the microelectronic device substrate, wherein the CMP slurry composition comprises at least one passivating agent, at least one barrier layer removal enhancer, at least one selectivity additive, at least one solvent, at least one acid-stable abrasive, and optionally at least one oxidizing agent, and optionally, incorporating the microelectronic device into a product, with the proviso that the CMP slurry composition is devoid of persulfate and phosphorous acid and/or a salt thereof.

Another aspect of the invention relates to a slurry kit for chemical mechanical polishing copper and barrier layer material, said slurry kit comprising in one containers:
a first slurry having a removal rate of copper that is greater than the removal rate of barrier and dielectric materials; and
a second slurry having a removal rate of barrier and dielectric materials that is similar to or greater than the removal rate of copper,
   wherein said first and second slurries comprise the following concentrations by weight based on the total weight of the composition:
from about 0.001 to about 10.0 wt. % passivating agent;
from about 0.01 to about 30.0 wt. % acid-stable abrasive; and
from about 20 to about 99.4 wt. % solvent.
   and wherein said first and second slurries are compatible to effect a single platen process for removing and polishing copper and barrier layer material.

Another aspect of the invention relates to the method of cleaning the polishing pad between the Step I and Step II polishing steps. In order to minimize cross contamination of the first and second slurries during their respective copper removal and barrier removal steps, a pad clean may be employed.

Other aspects, features and embodiments of the invention will be more fully apparent from the ensuing disclosure and appended claims.

### BRIEF DESCRIPTION OF THE DRAWINGS

FIG. 1 graphically illustrates the potentiometric titration of an aqueous slurry including 3.1 wt. % ATMI OS-70KL™ 70 nm silica, wherein the zeta potential at pH 4 is about −20 mV.

FIG. 2 graphically illustrates the potentiometric titration of an aqueous slurry including 4 wt. % acid-stable silica, wherein the zeta potential at pH 4 is about −50 mV.

FIG. 3 graphically illustrates the potentiometric titration of an aqueous slurry including 4 wt. % acid-stable silica and 0.4 wt. % 1,2,4-triazole passivating agent, wherein the zeta potential at pH 4 is about −40 mV.

FIG. 4 graphically illustrates the potentiometric titration of an aqueous slurry including 4 wt. % acid-stable silica and 0.4 wt. % aminotetrazole passivating agent, wherein the zeta potential at pH 4 is about −30 mV.

FIG. 5 illustrates the copper removal rate in Å min⁻¹ and the percent within wafer non-uniformity (WIWNU) relative to the downforce of the platen using the Step I CMP slurry including 0.05 wt. % 1,2,4-triazole.

FIG. 6 illustrates the planarization efficiency on patterned wafers at various downforces using two different Step I slurries of the present invention.

FIG. 7 illustrates the zeta potential and pH of a 10 wt. % silica slurry as a function of 1 M Fe(NO₃)₃.

FIG. 8 illustrates the removal rate of copper in Å min⁻¹ versus downforce for a blanket wafer using a Step I slurry comprising 5 wt. % hydrogen peroxide.

FIG. 9 illustrates the planarization efficiency on patterned wafers at various downforces using the Step I slurry according to the present invention.

FIG. 10 illustrates the sequential removal rate of copper when simulating the in situ, single platen processing sequence of the present invention.

### DETAILED DESCRIPTION OF THE INVENTION, AND PREFERRED EMBODIMENTS THEREOF

The present invention relates to chemical mechanical polishing compositions and process wherein copper and barrier layer material may be removed from a microelectronic device substrate having same thereon on a single processing platen. Specifically, the present invention relates to the in situ transformation of a Step I polishing composition into a Step II polishing composition on a single platen, i.e., without transference of the microelectronic device substrate to another platen for Step II processing.

As used herein, “about” is intended to correspond to ±5% of the stated value.

For ease of reference, “microelectronic device” corresponds to semiconductor substrates, flat panel displays, and microelectromechanical systems (MEMS), manufactured for use in microelectronic, integrated circuit, or computer chip applications. It is to be understood that the term “microelectronic device” is not meant to be limiting in any way and includes any substrate that will eventually become a microelectronic device or microelectronic assembly.

As defined herein, “dielectric capping material” corresponds to compounds including SiON, SiCOH, SiCN, and Si₃N₄ for example.

As used herein, within wafer non-uniformity (WIWNU) corresponds to a measurement of variation of material removal across the wafer. More specifically, WIWNU is the percent standard deviation of the amount of Cu removed for 49 measurement points, based on the average amount of Cu removed for said 49 measurement points, relative to the average amount of Cu removed for the 49 measurement points. Preferably, the WIWNU is less than about 5%.

As used herein, to “substantially remove” corresponds to the removal of the referenced material such that greater than 50% of the area between features has exposed the underlying material, preferably greater than 90% exposed, even more preferably greater than 95% exposed, and most preferably greater than 99% exposed, following the specific CMP processing step. For example, the Step I copper removal process should expose greater than 99% of the underlying barrier between features at the completion of the processing step.

In CMP, slurries are formulated to independently control the relative polishing rates between the different materials of the pattern to be polished. For example, the Step I slurry is used to rapidly remove bulk copper and to uniformly planarize the topography. The Step II slurry is used to remove the barrier layer material and optionally part of the cap and/or dielectric layer(s). Typically, the microelectronic device substrate having the copper layer and barrier layer material is positioned on a first platen for Step I polishing to remove and planarize the copper layer and then subsequently transferred to another platen for Step II polishing to remove the barrier layer material. The use of an additional platen for Step II processing is disadvantageous in part due to throughput considerations as well as tool constraints.

To chemically mechanically polish the microelectronic device substrate on a single platen requires the sequential introduction of the Step I slurry and the Step II slurry to the same platen. Even with a rinse in between the introduction of the two different slurries to the same platen, pH shock, incompatibility between chemistries and/or abrasives and other problems degrade polish performance or cause defectivity problems.

The present invention overcomes the problems associated with prior art single platen CMP formulations and processes. Specifically, the present invention relates to Step I and Step II CMP formulations which are compatible with one another and as such, may be sequentially introduced to the same platen. Additionally, one embodiment of the present invention relates to a single-platen, multistep CMP process that includes pad cleaning steps between each step to minimize the influence of the slurry of one step on a subsequent step. Further, another aspect of the present invention relates to a CMP process including the in situ transformation of a Step I polishing composition into a Step II polishing composition on a single platen, i.e., without transference of the microelectronic device substrate to a second platen for Step II processing thereon. The CMP compositions and process described herein ensure the rapid, efficient and selective removal and planarization of bulk copper during Step I and the selective removal of residual copper, barrier layer material, and optionally partial removal of the dielectric stack during Step II, wherein both Step I and Step II processing is effectuated on the same platen.

As defined herein, “Step I” corresponds to the CMP process of removing and planarizing bulk copper from the surface of a substrate having bulk copper thereon, as well as the slurry formulation used during said CMP process. In addition, the Step I process may include “soft landing” or “touchdown,” which corresponds to some point in the Step I polishing process whereby the downforce of the polisher may be decreased to reduce dishing and/or erosion of the copper on the surface of the substrate. “Soft landing” or “touchdown” is preferably ceased at a detectable processing endpoint. Upon reaching the endpoint, over-polishing may begin. Over-polishing is performed to remove the copper residuals from the surface of the barrier material, while minimizing additional dishing or erosion of the copper features.

As defined herein, “Step II” corresponds to the CMP process of removing residual copper, barrier layer material, a dielectric capping material such as SiON or optionally some dielectric from the surface of a microelectronic device substrate having same thereon, as well as the slurry formulation used during said CMP process. Often the Step II process is controlled with a fixed process time, but the process may be controlled by means of an endpoint system and include an over-polishing step after the endpoint of the Step II polish has been detected.

As defined herein, “barrier layer material” corresponds to any material used in the art to seal the metal lines, e.g., copper interconnects, to minimize the diffusion of said metal, e.g., copper, into the dielectric material. Preferred barrier layer materials include tantalum, titanium, ruthenium, hafnium, tungsten, and other refractory metals and their nitrides and silicides. Specific reference to tantalum hereinafter in the broad description of the invention is meant to provide an illustrative example of the present invention and is not meant to limit same in any way.

The Step I CMP formulation of the present invention includes at least one oxidizing agent, at least one passivating agent, at least one chelating agent, abrasive, at least one solvent, and optionally at least one pH adjusting agent, present in the following ranges, based on the total weight of the composition:

| component | % by weight |
|---|---|
| oxidizing agent(s) | about 0.05% to about 20.0% |
| passivating agent(s) | about 0.001% to about 10.0% |
| chelating agent(s) | about 0.001% to about 20.0% |
| abrasive(s) | about 0.01% to about 20.0% |
| solvent(s) | about 30% to about 99.4% |
| pH adjusting agent(s) | 0 to about 1% |

The pH of the Step I formulation is in a range from about 2 to about 12, preferably in a range from about 4 to about 6, even more preferably in a range from about 4.5 to about 5.5. The range of mole ratios for solvent(s) relative to oxidizing agent(s) is about 1:1 to about 100:1, preferably about 10:1 to about 80:1, and most preferably about 25:1 to about 45:1, the range of mole ratios for solvent(s) relative to chelating agent (s) is about 1:1 to about 250:1, preferably about 100:1 to about 150:1, the range of mole ratios for solvent(s) relative to passivating agent(s) is about 500:1 to about 8000:1, preferably about 500:1 to about 1000:1 or about 6500:1 to about 7500:1, and the range of mole ratios for solvent(s) relative to abrasive(s) is about 50:1 to about 700:1, preferably about 200:1 to about 600:1.

In the broad practice of the invention, the Step I CMP formulation may comprise, consist of, or consist essentially of at least one oxidizing agent, at least one passivating agent, at least one chelating agent, abrasive(s), solvent(s), and optionally at least one pH adjusting agent(s). In general, the specific proportions and amounts of oxidizing agent(s), passivating agent(s), chelating agent(s), abrasive(s), solvent(s) and optional pH adjusting agent(s), in relation to each other, may be suitably varied to provide the desired removal action of the bulk copper layer from the microelectronic device substrate having same thereon, as readily determinable within the skill of the art without undue effort. Importantly, the Step I CMP formulation is devoid of persulfate and phosphorous acid and/or a salt thereof.

In a particularly preferred embodiment of the present invention, the Step I formulation includes the following components present in the following ranges, based on the total weight of the composition:

| component | % by weight |
|---|---|
| oxidizing agent(s) | about 3.0% to about 6.0% |
| passivating agent(s) | about 0.01% to 0.7% |
| chelating agent(s) | about 1.0% to about 4.0% |
| abrasive(s) | about 0.7% to about 1.3% |
| solvent(s) | about 88% to about 95.2% |
| pH adjusting agent(s) | about 0.001% to about 0.5% |
| pH | About 4.5 to about 5.5 |

The abrasive component of the Step I formulation as used herein may be of any suitable type, including, without limitation, oxides, metal oxides, silicon nitrides, carbides, etc. Specific examples include silica, alumina, silicon carbide, silicon nitride, iron oxide, ceria, zirconium oxide, tin oxide, titanium dioxide, and mixtures of two or more of such components in suitable form, such as grains, granules, particles, or other divided form. Alternatively, the abrasive can include composite particles formed of two or more materials, e.g., NYACOL® alumina-coated colloidal silica (Nyacol Nano Technologies, Inc., Ashland, Mass.) or mixtures of different particle size distributions of said abrasives or any combination thereof. Organic polymer particles, e.g., including thermoset and/or thermoplastic resin(s), can be utilized as abrasives. Useful resins in the broad practice of the present invention include epoxies, urethanes, polyesters, polyamides, polycarbonates, polyolefins, polyvinylchloride, polystyrenes, polyolefins, and (meth)acrylics. Mixtures of two or more organic polymer particles can be used as the abrasive medium, as well as particles comprising both inorganic and organic components. Preferably, the abrasives are selected or modified to be compatible with acidic media.

The preferred abrasive component of the Step I formulation has a diameter in a range from about 10 nm to about 1000 nm, preferably about 20 nm to about 90 nm.

The oxidizing agent of the Step I composition includes any substance which removes metal electrons and raises the atomic valence and includes, but is not limited to, hydrogen peroxide (H₂O₂), ferric nitrate (Fe(NO₃)₃), potassium iodate (KIO₃), potassium permanganate (KMnO₄), nitric acid (HNO₃), ammonium chlorite (NH₄ClO₂), ammonium chlorate (NH₄ClO₃), ammonium iodate (NH₄IO₃), ammonium perborate (NH₄BO₃), ammonium perchlorate (NH₄ClO₄), ammonium periodate (NH₄IO₃), tetramethylammonium chlorite ((N(CH₃)₄)ClO₂), tetramethylammonium chlorate ((N(CH₃)₄)ClO₃), tetramethylammonium iodate ((N(CH₃)₄)IO₃), tetramethylammonium perborate ((N(CH₃)₄)BO₃), tetramethylammonium perchlorate ((N(CH₃)₄)ClO₄), tetramethylammonium periodate ((N(CH₃)₄)IO₄), urea hydrogen peroxide ((CO(NH₂)₂)H₂O₂). The preferred oxidizing agent for the Step I composition of the present invention is hydrogen peroxide.

The term chelating agent as used in the present Step I composition is intended to mean any substance that in the presence of an aqueous solution solubilizes or etches the oxidized copper material. Copper chelating agents and etchants useful in the present invention include but are not limited to inorganic acids and organic acids, amines and amino acids (i.e. glycine, alanine, citric acid, acetic acid, maleic acid, oxalic acid, malonic acid, phthalic acid, succinic acid), nitrilotriacetic acid, iminodiacetic acid, ethylenediamine, CDTA, and EDTA. A preferred chelating agent is glycine.

The term passivating agent as used herein, is intended to mean any substance that reacts with the fresh copper surface and/or oxidized copper thin film to passivate the copper layer and prevent excessive etching of the copper surface during CMP. Preferably, the passivating agent in the Step I composition of the invention may comprise one or more inhibitor components including for example, triazoles, such as 1,2,4-triazole (TAZ), or triazoles substituted with substituents such as C₁-C₈ alkyl, amino, thiol, mercapto, imino, carboxy and nitro groups, such as benzotriazole, tolyltriazole, 5-phenyl-benzotriazole, 5-nitro-benzotriazole, 3-amino-5-mercapto-1,2,4-triazole, 1-amino-1,2,4-triazole, hydroxybenzotriazole, 2-(5-amino-pentyl)-benzotriazole, 1-amino-1,2,3-triazole, 1-amino-5-methyl-1,2,3-triazole, 3-amino-1,2,4-triazole, 3-mercapto-1,2,4-triazole, 3-isopropyl-1,2,4-triazole, 5-phenylthiol-benzotriazole, halo-benzotriazoles (halo=F, Cl, Br or I), naphthotriazole, and the like, as well as thiazoles, tetrazoles, imidazoles, phosphates, thiols and azines such as 2-mercaptobenzimidazole (MBI), 2-mercaptobenzothiazole, 4-methyl-2-phenylimidazole, 2-mercaptothiazoline, 5-aminotetrazole, 5-amino-1,3,4-thiadiazole-2-thiol, 2,4-diamino-6-methyl-1,3,5-triazine, thiazole, triazine, methyltetrazole, 1,3-dimethyl-2-imidazolidinone, 1,5-pentamethylenetetrazole, 1-phenyl-5-mercaptotetrazole, diaminomethyltriazine, imidazoline thione, mercaptobenzimidazole, 4-methyl-4H-1,2,4-triazole-3-thiol, 5-amino-1,3,4-thiadiazole-2-thiol, benzothiazole, tritolyl phosphate, imidazole, indiazole, etc. Dicarboxylic acids such as oxalic acid, malonic acid, succinic acid, nitrilotriacetic acid, iminodiacetic acid, and combinations thereof are also useful passivating agents. Importantly, the ratio of triazole compound to benzotriazole compound in the Step I CMP formulation is most preferably less than 1:1 or greater than 100:1. Preferred passivating agents include triazoles and their derivatives. In a specific embodiment, the preferred passivating agent is 1,2,4-triazole (TAZ).

In a particularly preferred embodiment, the Step I CMP slurry is substantially devoid of polyethylene oxide, a polyoxyethylene alkyl ether, a polyoxypropylene alkyl ether, a polyoxyethylenepolyoxypropylene alkyl ether and a polyoxyalkylene addition polymer. In another particularly preferred embodiment, the Step I CMP slurry is substantially devoid of alkylamines or alkoxyalkylamines having 4 to 6 carbon atoms. In still another particularly preferred embodiment, the Step I CMP slurry is substantially devoid of aliphatic carboxylic acids such as lauric acid, linolic acid, myristic acid, palmitic acid, stearic acid, oleic acid, sebacic acid, and dodecanedoic acid. As defined herein, “substantially devoid” corresponds to less than about 0.5 wt. %, more preferably less than 0.05 wt. %, and most preferably less than 0.005 wt. % of the composition, based on the total weight of said composition.

Depending on the desired results of the Step I CMP planarization, the concentration of the passivating agent may be varied to adjust the removal rate of copper without compromising the planarization efficiency. Two proposed Step I CMP slurries include formulations A and B, as introduced hereinbelow, based on the total weight of the composition:

Formulation A

| | | |
|---|---|---|
| glycine | 3 | wt. % |
| 1,2,4-triazole | 0.4 | wt. % |
| acid-stabilized silica | 1 | wt. % |
| H₂O₂ | 5 | wt. % |
| KOH or HNO₃ | 0.02-0.05 | wt. % |

| | |
|---|---|
| water | balance |
| pH | 5.0-5.1 |

Formulation B

| | | |
|---|---|---|
| glycine | 3 | wt. % |
| 1,2,4-triazole | 0.05 | wt. % |
| acid-stabilized silica | 1 | wt. % |
| H₂O₂ | 5 | wt. % |
| HNO₃ | 0.005 | wt. % |

| | |
|---|---|
| water | balance |
| pH | 5.1 |

The Step II CMP formulation of the present invention includes at least one oxidizing agent, at least one passivating agent, at least one barrier layer removal enhancer, at least one selectivity additive, abrasive, solvent, and optionally at least one pH adjusting agent, present in the following ranges, based on the total weight of the composition:

| component | % by weight |
|---|---|
| oxidizing agent(s) | about 0% to about 20.0% |
| passivating agent(s) | about 0.01% to about 10.0% |
| barrier layer removal enhancer(s) | about 0.01% to about 10.0% |
| selectivity additive(s) | about 0.001% to about 10.0% |
| abrasive(s) | about 1.0% to about 30.0% |
| solvent(s) | about 20% to about 98.98% |
| pH adjustment agent(s) | 0 to about 1% |

The pH of the Step II formulation is in a range from about 2 to about 12, preferably in a range from about 2 to about 5. The range of mole ratios for solvent(s) relative to oxidizing agent(s) is about 100:1 to about 2000:1, preferably about 700:1 to about 1300:1, and most preferably about 1000:1 to about 1200:1, the range of mole ratios for solvent(s) relative to passivating agent(s) is about 500:1 to about 3000:1, preferably about 1500:1 to about 2000:1, and most preferably about 1650:1 to about 1800:1, the range of mole ratios for solvent(s) relative to abrasive(s) is about 1:1 to about 100:1, preferably about 20:1 to about 60:1, the range of mole ratios for solvent(s) relative to barrier layer removal enhancer(s) is about 1000:1 to about 4000:1, preferably about 2500:1 to about 3000:1, and the range of mole ratios for solvent(s) relative to selectivity additive(s) is greater than 50,000:1.

In the broad practice of the invention, the Step II CMP formulation may comprise, consist of, or consist essentially of at least one oxidizing agent, at least one passivating agent, at least one barrier layer removal enhancer, at least one selectivity additive, abrasive material(s), solvent(s), and optionally pH adjusting agent(s). In general, the specific proportions and amounts of oxidizing agent(s), passivating agent(s), barrier layer removal enhancer(s), selectively additive(s), abrasive material(s), solvent(s), and optional pH adjusting agent(s), in relation to each other, may be suitably varied to provide the desired removal action of the barrier layer material from the microelectronic device substrate having same thereon, as readily determinable within the skill of the art without undue effort. Importantly, the Step II CMP formulation is devoid of persulfate and phosphorous acid and phosphoric acid and/or a salt thereof.

In a particularly preferred embodiment of the present invention, the formulation includes the following components present in the following ranges, based on the total weight of the composition:

| component | % by weight |
|---|---|
| oxidizing agent(s) | about 0.05% to about 0.5% |
| passivating agent(s) | About 0.1% to 0.4% |
| barrier layer removal enhancer(s) | about 0.1% to about 0.5% |
| selectivity additive(s) | about 0.05% to about 0.5% |
| abrasive(s) | about 5.0% to about 12.0% |
| solvent(s) | about 86.1% to about 94.7% |
| pH adjustment agent(s) | about 0.001% to about 0.5% |
| pH | about 3 to about 4 |

In a particularly preferred embodiment, the Step II formulation may be represented by Formulation C:

Formulation C

| | | |
|---|---|---|
| 1,2,4-triazole | 0.2 | wt. % |
| phthalic acid | 0.3 | wt. % |
| polyacrylic acid (2,000 MW) | 0.1 | wt. % |
| acid-stabilized silica | 10 | wt. % |
| H₂O₂ | 0.15 | wt. % |
| KOH or HNO₃ | 0.06-0.09 | wt. % |

| | |
|---|---|
| water | balance |
| pH | about 3.5 |

The preferred abrasive component of the Step II formulation is also acid-stable silica. The preferred diameter of the Step II abrasive is in a range from about 10 nm to about 1000 nm, preferably about 20 nm to about 90 nm.

The oxidizing agents contemplated for the Step II CMP formulation include those enumerated herein for the Step I CMP formulation. The oxidizing agents in the Step I and Step II formulations may be the same as, or different from one another. Preferably, the Step II oxidizing agent is hydrogen peroxide.

The passivating agents contemplated for the Step II CMP formulation preferably include those enumerated herein for the Step I CMP formulation. The passivating agents in the Step I and Step II formulations may be the same as, or different from one another. In the preferred embodiment, both the Step I and the Step II employ the same passivating agent. Furthermore, the passivating agent should not have a measurable effect on the zeta potential of the abrasive in the preferred pH regime. Preferably, 1,2,4-triazole is the Step II passivating agent.

The barrier layer removal enhancer is added to increase the rate of removal of barrier layer material during Step II processing. Preferably, the removal enhancer in the Step II formulation of the invention may comprise one or more barrier layer removal components including for example, phthalic acid, salicylic acid, benzoic acid, and other aromatic carboxylic acids. Preferably, the Step II barrier layer removal enhancer is phthalic acid.

The selectivity additive is added to reduce the removal rate of copper during the Step II process to control selectivity. In a preferred embodiment, some copper is removed (at a nonzero rate) to prevent residual copper defects. Preferably, the selectivity additive in the Step II formulation of the invention may comprise one or more selectively components including for example, poly(acrylic acid), anionic surfactants, and other polyelectrolytes. Preferably, the selectivity additive is poly(acrylic acid) (PAA) with a molecular weight in the range from about 400 to about 8,000,000.

In a particularly preferred embodiment, the Step II CMP formulation of the invention includes acid-stable silica, 1,2,4-triazole, H₂O₂, phthalic acid and PAA in an aqueous solution at a pH of about 3.5.

The solvents employed in the Step I and Step II formulations of the invention may be single component solvents or multicomponent solvents, depending on the specific application. The solvents in the Step I and Step II formulations may be the same as, or different from one another, preferably the same as one other. In one embodiment of the invention, the solvent in the CMP compositions is water. In another embodiment, the solvent comprises one or more of an organic solvent, e.g., methanol, ethanol, propanol, butanol, ethylene glycol, propylene glycol, glycerin, etc. In yet another embodiment, the solvent comprises a water-organic solvent(s) solution. A wide variety of solvent types and specific solvent media may be employed in the general practice of the invention to provide a solvating/suspending medium in which the abrasive is dispersed and in which the other components are incorporated to provide a composition of appropriate character, e.g., of slurry form, for application to the platen of the CMP unit to provide a desired level of polishing of the copper and barrier layer material on the microelectronic device substrate.

Acids and bases may be optionally employed for pH adjustment in the Step I and Step II CMP formulations of the invention. Illustrative acids include, by way of example, formic acid, acetic acid, propanoic acid, butanoic acid, pentanoic acid, isovaleric acid, hexanoic acid, heptanoic acid, octanoic acid, nonanoic acid, lactic acid, hydrochloric acid, nitric acid, sulfuric acid, hydrofluoric acid, malic acid, fumaric acid, malonic acid, glutaric acid, glycolic acid, salicylic acid, 1,2,3-benzenetricarboxylic acid, tartaric acid, gluconic acid, citric acid, phthalic acid, pyrocatechoic acid, pyrogallol carboxylic acid, gallic acid, tannic acid, and mixtures including two or more acids of the foregoing or other types. Illustrative bases include, by way of example, potassium hydroxide, ammonium hydroxide and tetramethylammonium hydroxide (TMAH), tetraethylammonium hydroxide, trimethyl hydroxyethylammonium hydroxide, methyl tri (hydroxyethyl) ammonium hydroxide, tetra(hydroxyethyl)ammonium hydroxide, and benzyl trimethylammonium hydroxide. Preferably, the base is KOH.

In addition, the Step I and II CMP formulations may further comprise additional components including, but not limited to, defoamers, biocides, rheology agents and surfactants.

In another embodiment, the abrasive of the Step I CMP formulation described hereinabove is a cationic abrasive, such as alumina, and the abrasive of the Step II CMP formulation described hereinabove is an anionic abrasive material that has been processed to become cationic, thus increasing the compatibility of the Step I and Step II abrasive materials at the single platen during CMP processing.

As introduced in the Background section, generally, Step I slurries include alumina, which is cationic, and Step II slurries include silica, which is anionic. In order to effectuate one platen CMP processing, the abrasive materials must be electrically repulsive, i.e., both the Step I and Step II abrasive must have the same charge. As such, if the abrasives typically used in Step I and Step II CMP formulations are used, i.e., alumina and silica, respectively, the charge of one of them must be reversed at or before introduction of the Step II slurry to the single platen.

Towards that end, it was discovered that the anionic charge on silica may be reversed by exposing silica, in an acidic environment, to metal ions such as Fe³⁺, Ca²⁺, Ba²⁺, Co²⁺, and/or cetyl trimethyl ammonium bromide (CTAB). This charge reversal will assist in the provision of compatibility between the Step I slurry and the Step II slurry, particularly when a cationic abrasive such as alumina is included in the Step I slurry. Most preferably, the charge reversal is effectuated during the manufacture of the slurry so as to minimize the exposure of the wafer to non-adsorbed metal ions such as Fe³⁺, Ca²⁺, Ba²⁺, Co²⁺, and/or CTAB.

The CMP formulations of the invention may be provided as a single package formulation or a multi-part formulation that is mixed at the point of use or in a storage tank upstream of the tool. The advantage of a multi-part formulation resides in its extended shelf life relative to single-package formulations. A single package formulation is more susceptible to decomposition and change of its properties over time, in relation to a multi-part formulation, due to the presence of the oxidizer in the single-package CMP formulation. The concentrations of the single-package formulation or the individual packages of the multi-part formulations may be widely varied in specific multiples, i.e., more dilute or more concentrated, in the broad practice of the invention, and it will be appreciated that the CMP formulations of the invention can variously and alternatively comprise, consist or consist essentially of any combination of ingredients consistent with the disclosure herein.

In one embodiment, each single ingredient of the CMP formulation is individually delivered to the polishing table for combination at the table, to constitute the CMP formulation for use. In another embodiment, the CMP formulation is formulated as a two-part formulation in which the first part comprises abrasive and passivating agent in the appropriate solvent, and the second part comprises oxidizing agent and chelating agent. In still another embodiment, the CMP formulation is formulated as a two-part formulation in which the first part comprises abrasive, passivating agent and chelating agent in the appropriate solvent, and the second part comprises the oxidizer. The multi-part formulation embodiments disclosed herein are not meant to be limiting in any way and may include alternative combinations. In all of these various embodiments, the mixing of ingredients or parts to form the final formulation occurs at the point of use (e.g., mixing at the polishing table, polishing belt or the like), in an appropriate container shortly before reaching the polishing table, or at the CMP formulation manufacturer and/or supplier.

In yet another embodiment, the individual parts of the formulations described herein may be provided at concentrations at least three to four times greater than preferred during polishing. Accordingly, the concentrated formulation parts may be diluted with the appropriate solvent at the point of use (e.g., mixing at the polishing table, polishing belt or the like) or in an appropriate container shortly before reaching the polishing table. For example, a concentrated CMP slurry comprising the range of mole ratios described herein may be diluted in a range from about 0.1:1 to about 4:1, preferably about 11:1 to about 3:1, with a solvent to form any of the preferred compositions described herein. Preferably, the diluting solvent comprises the solvent of the specific CMP slurry composition.

Accordingly, another aspect of the invention relates to a kit including, in one or more containers, the components adapted to form the formulations of the invention as described hereinabove. The containers of the kit may be NOWPak® containers (Advanced Technology Materials, Inc., Danbury, Conn., USA) including fluoropolymer-based materials.

In practice, the Step I formulation is delivered to the platen for Step I processing, which may be divided into three sub-steps: bulk copper removal, “soft landing,” and over-polishing. The processing conditions of the bulk copper removal sub-step include a platen pad downforce in a range from about 0.1 psi to about 7 psi, preferably about 3 psi to about 7 psi. Referring to FIG. 8, which represents the bulk copper removal of a blanket sample wafer using a Step I slurry comprising 5 wt. % H₂O₂, it can be seen that higher throughput can be achieved using a higher downforce.

The processing conditions of the soft landing sub-step include a platen pad downforce in a range from about 0.1 psi to about 7 psi, preferably less than or equal to 3 psi. The soft landing sub-step is ceased when the endpoint is reached, as readily determinable by one skilled in the art. Endpoint methods include but are not limited to friction or torque measurements, eddy current thickness measurements, film reflectance measurements, imaging analysis, and chemical sensing. The processing conditions of the over-polish include a platen pad downforce in a range from about 0.1 psi to about 4 psi, preferably less than or equal to 3 psi. The length of time of the over-polish is readily determinable by skilled in the art. In a preferred embodiment, the downforce of the bulk copper removal is greater than the downforce of the soft-landing which is greater than the downforce of the over-polish.

The copper removal rate can be adjusted over a substantial range as determined by those skilled in the art. The preferred copper to tantalum selectivity during Step I processing may be in a range from about 100:1 to about 1,000:1, preferably about 400:1 to about 1000:1.

Following completion of the Step I CMP process, the platen and microelectronic device substrate may be rinsed with a solvent such as water or a pad cleaning agent. Preferably, the solvent is the same as that used in the Step I and/or Step II CMP formulations described herein, e.g., water. The pad cleaning chemistry is preferably a solution of a carboxylic acid and its ammonium salt, such as the commercial product LP-12 (ATMI, Danbury, Conn., USA), more preferably, a 10:1 dilution (with water) of LP-12.

Thereafter, the Step II CMP formulation is delivered to the platen for Step II processing. Importantly, the Step II CMP formulation may be made by the mixing of ingredients or parts to form the final formulation at the point of use (e.g., mixing at the polishing table, polishing belt or the like), in an appropriate container shortly before reaching the polishing table, or at the CMP formulation manufacturer and/or supplier. The processing conditions of Step II include a downforce in a range from about 0.1 psi to about 7 psi, preferably about 2.5 psi to about 4 psi.

The Step II slurry may be tuned to alter the removal rates of copper relative to barrier layer material relative to dielectric stack. Specifically, the selectivities may be tuned by adjustment of chemical composition, abrasive loading, downforce, and other processing parameters. Accordingly, the Step II slurry may be tuned for different integration requirements, as readily determinable by one skilled in the art.

Table 1 includes the removal rate of copper, tantalum, TEOS oxide and SiON during Step II processing of a blanket sample wafer at a downforce of 3 psi using a Step II CMP formulation of the invention.

TABLE 1
Removal rate of Cu, Ta, dielectric and SiON using the
Step II CMP formulation of the present invention.

| Layer | removal rate/Å min⁻¹ |
|---|---|
| Copper | 464 |
| Tantalum | 840 |
| TEOS oxide | 1032 |
| SiON | 1722 |

The removal rate selectivities of the different materials may be adjusted over a broad range to satisfy different integration requirements. This selection may encompass the range from a non-selective process to a highly selective process. Preferably, the copper removal rate during Step II is in a range from about 100 Å min⁻¹ to about 1,500 Å min⁻¹, most preferably in a range from about 300 Å min⁻¹ to about 1000 Å min⁻¹. The preferred copper to tantalum selectivity and copper to dielectric selectivity during Step II may be in a range from about 10:1 to about 1:10, more preferably in the range from about 1:1 to 1:10. Specific targets are driven by process integration requirements.

In one embodiment, following completion of each step of the CMP process, the polished substrate may be removed from the platen prior to the next processing step. The polishing pad may be thoroughly cleaned prior to polishing of a substrate to prevent carryover of slurry. Carryover of slurry may alter the material removal rates during the subsequent processing step, therefore the pad must be cleansed with solvent or pad cleaning solution prior to subsequent processing. Preferably, the solvent is the same as that used in the Step I and/or Step II CMP formulations described herein, e.g., water. The pad cleaning chemistry is preferably a solution of a carboxylic acid and its ammonium salt, such as the commercial product LP-12 (ATMI, Danbury, Conn., USA), more preferably, a 10:1 dilution (with water) of LP-12.

In another embodiment, following completion of Step I of the CMP process, the Step II CMP formulation is introduced directly to the polishing pad having the Step I CMP formulation thereon, whereby the concentration of the Step I components are accounted for when determining how much of the Step II components must be added to the platen pad, as readily determined by one skilled in the art. In yet another embodiment, following completion of Step I of the CMP process, the polishing pad is rinsed with the Step II CMP formulation.

The CMP process described herein corresponds to an in situ transition of a Step I polishing composition into a Step II polishing composition on a single platen, i.e., without transference of the microelectronic device substrate to a second platen for Step II processing. This is possible because of the substantial compatibility of the Step I and Step II CMP formulations and the effectiveness of the pad cleaning step. It is to be appreciated that although the present process has been described as being carried out on a single platen, the invention is not limited as such. For example, the present process may include Step I processing on one platen using the Step I slurry followed by Step II processing on a different platen using the Step II slurry.

The following Examples are merely illustrative of the invention and are not intended to be limiting.

### Example 1

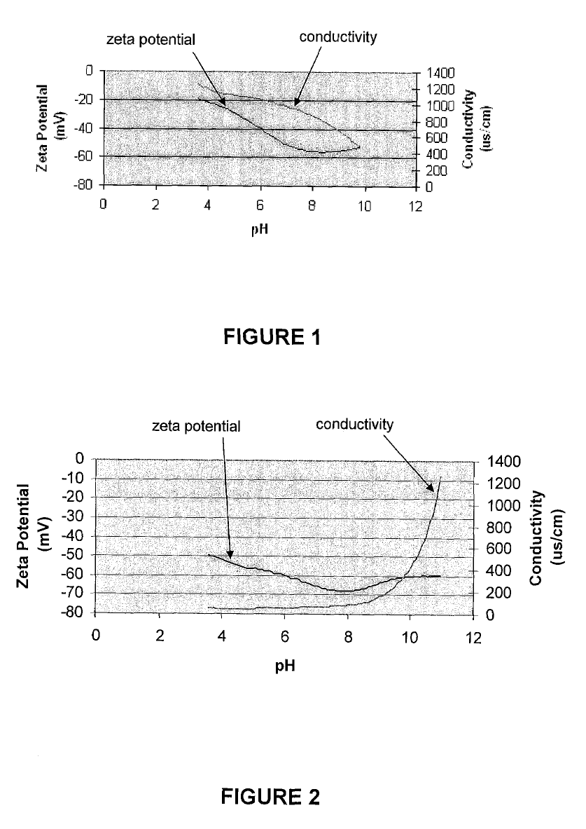

As introduced hereinabove, preferably, the abrasive component of the present invention is stable in acidic media, for example an acid-stable colloidal silica having a zeta potential less than about −50 mV, i.e., more negative, in a pH range of 4 and above. Comparing FIGS. 1 and 2, which correspond to a standard 3.1 wt. % ATMI OS70KL™ 70 nm silica aqueous slurry and a 4 wt. % acid-stable silica aqueous slurry, respectively, it can be seen that the acid-stable silica slurry is highly negative throughout the pH range, which ensures better colloidal stability, i.e., the charged particles repel one another and thus overcome the natural tendency to aggregate. Moreover, the stability in the acidic range ensures pH compatibility between the liquid components of the slurry and the abrasive.

### Example 2

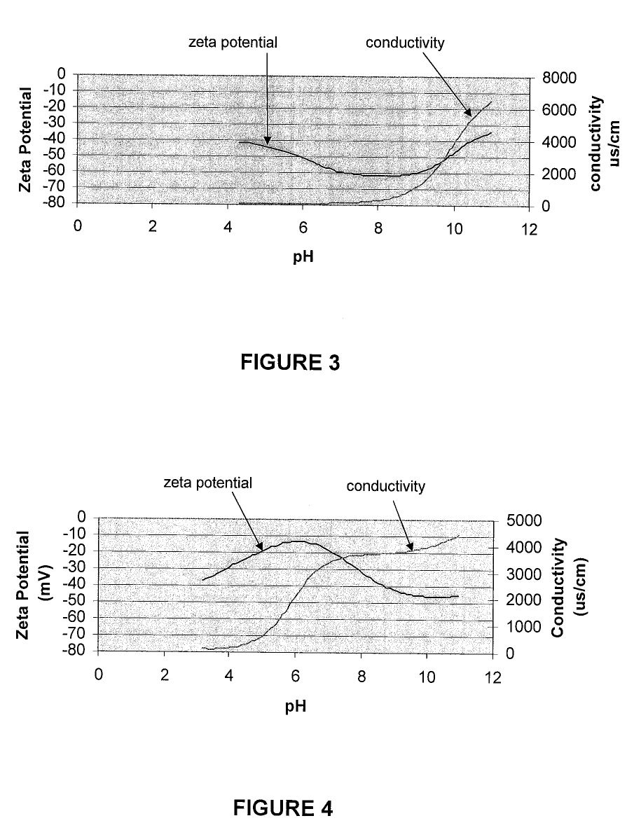

FIG. 3 illustrates the potentiometric titration of an aqueous slurry including 4 wt. % acid-stable silica and 0.4 wt. % 1,2,4-triazole passivating agent. Importantly, the zeta potential throughout the pH range remains substantially negatively charged, similar to that of the silica in the absence of the passivating agent (see, e.g., FIG. 2), which indicates negligible interaction between the abrasive and the passivating agent. By way of illustration, FIG. 4 represents an experiment where substantial interaction between the abrasive and the passivating agent was observed. FIG. 4 illustrates the electrostatic potential of an aqueous slurry including 4 wt. % acid-stable silica and 0.4 wt. % 5-amino, 1H-tetrazole passivating agent. Comparing the zeta potential curve of FIG. 4 with that of FIG. 2 (i.e., the acid-stable silica in the absence of passivating agent), it can be seen that the curves are distinctly different in shape over the pH range. This distinct difference in electrostatic potential is representative of interaction between the abrasive and the passivating agent, which is undesirable.

### Example 3

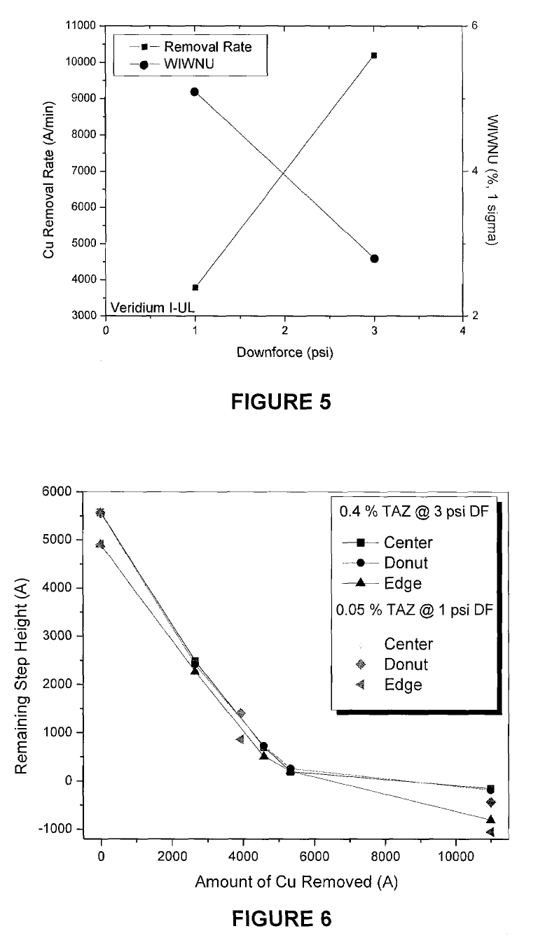

Referring to FIGS. 5 and 6, the planarization efficiency using Formulations A and B is illustrated. FIG. 5 illustrates the removal rate of Cu, in Å min⁻¹, and the WIWNU as a function of downforce using the Step I CMP formulation B. It can be seen that the removal rate of copper is high and the WIWNU is low, which corresponds to the preferred results during Step I Cu planarization processes. Further, referring to FIG. 6, it can be seen that formulation B has about the same planarization efficiency at one-third the downforce pressure as formulation A.

### Example 4

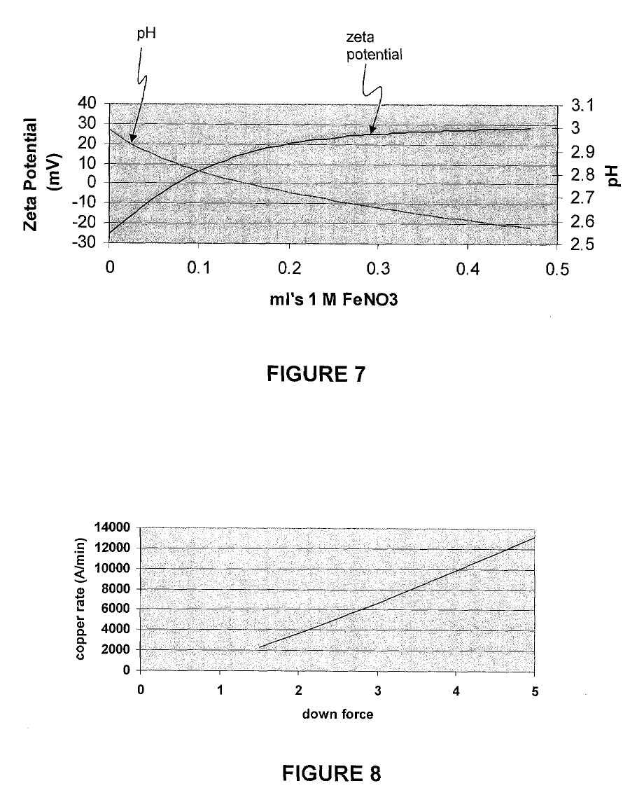

Referring to FIGS. 1, 2 and 7, the charge reversal on silica is illustrated whereby a 10 wt. % silica slurry was titrated with 1M Fe(NO₃)₃. It can be seen that in the absence of the Fe³⁺ ions, the zeta potential of the silica slurry is about −25 mV at a pH of about 3, and thus the silica material is anionic. Following the addition of just 0.5 mmol of Fe³⁺, the zeta potential is about +30 mV at a pH of about 2.58, and thus the silica material underwent a charge reversal to become cationic as the Fe³⁺ is added. This charge reversal is useful when different, but electronically compatible abrasive material, is desirable for use during the two-step CMP process.

### Example 5

The removal rate and selectivity during Step I removal may be tuned through adjustment of the chemical constituents and abrasive concentration. For example, Table 2 includes the removal rate of copper and the removal rate of tantalum during Step I processing of a blanket sample wafer at a downforce of 3 psi as a function of oxidizing agent concentration using formulation A described herein.

TABLE 2
Copper and tantalum removal rates as a function of oxidizing
agent during Step I processing of a blanket sample wafer.

| | Cu removal | Ta removal | |
|---|---|---|---|
| conc. H₂O₂/wt. % | rate/Å min⁻¹ | rate/Å min⁻¹ | selectivity |
| 3 | 9,000 | 11 | 818 |
| 5 | 6,500 | 14 | 465 |

Referring to Table 2 and FIG. 8, it can be seen that good copper removal rates and excellent copper to tantalum selectivity are achievable using the Step I formulation described herein.

### Example 6

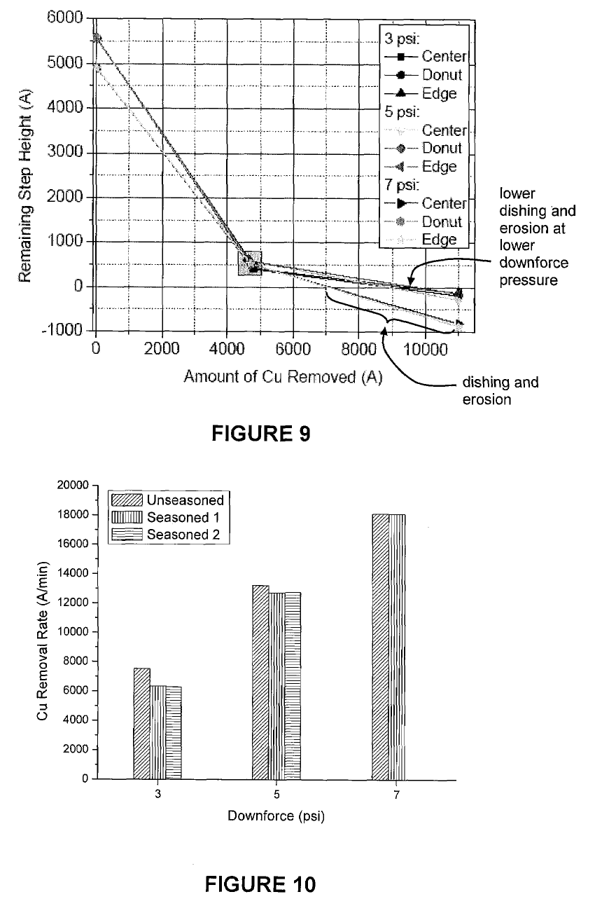

FIG. 9 illustrates the planarization efficiency of copper on patterned wafers as a function of downforce, i.e., 3 psi to 7 psi. The planarization efficiency is illustrated by the amount of copper removed as a function of the remaining step height. High planarization efficiency corresponds to a steep slope, i.e, a fast reduction of step height as displayed between 0 Å and 5,000 Å of copper removed. Importantly, the varying downforces result in almost identical planarization curves using formulation A described herein. However, a lower downforce, e.g., 3 and 5 psi, has the benefit of lower dishing and erosion at the surface of the substrate upon exposing the barrier layer.

### Example 7

FIG. 10 illustrates the compatibility of the Step I and Step II composition when employed on a single pad for polishing wafers. The first bar at each respective downforce, marked “unseasoned,” displays the copper removal rate utilizing only the Step I slurry. The second and third bar at each respective downforce, marked “seasoned,” illustrate the Cu removal rate of a blanket wafer that was polished with Step I slurry following a wafer polish employing Step II slurry on the same pad. The differences between the “seasoned” and the “unseasoned” removal rates are negligible. Thus, the two slurries are highly compatible when employed on a single pad. Inspection of a patterned test wafer after the full sequence of polishing steps on the same pad revealed a minimal amount of surface defects. This demonstrates that the two slurry formulations are highly compatible when used in a single platen process.

While the invention has been described herein in reference to specific aspects, features and illustrative embodiments of the invention, it will be appreciated that the utility of the invention is not thus limited, but rather extends to and encompasses numerous other variations, modifications and alternative embodiments, as will suggest themselves to those of ordinary skill in the field of the present invention, based on the disclosure herein. Correspondingly, the invention as hereinafter claimed is intended to be broadly construed and interpreted, as including all such variations, modifications and alternative embodiments, within its spirit and scope.

1. A CMP slurry composition comprising at least one passivating agent, at least one solvent, at least one abrasive, and optionally at least one pH adjustment agent, wherein said composition is further characterized by comprising at least one of the following components (I) or (II):
(I) at least one oxidizing agent and at least one chelating agent, wherein said composition is useful for removing and planarizing copper; or
(II) at least one barrier layer removal enhancer, at least one selectivity additive, and optionally at least one oxidizing agent, wherein said composition is useful for the selective removal and polishing of barrier layer material.

2. (canceled)

3. (canceled)

4. (canceled)

5. The CMP slurry composition of claim 1, comprising component (II), wherein the abrasive comprises an acid-stable abrasive species selected from the group consisting of silica, acid-stable silica, alumina, silicon carbide, silicon nitride, iron oxide, ceria, zirconium oxide, tin oxide, titanium dioxide, organic polymer particles, epoxies, urethanes, polyesters, polyamides, polycarbonates, polyolefins, polyvinylchloride, polystyrenes, polyolefins, (meth)acrylics, alumina-coated colloidal silica and mixtures of two or more of such components;
wherein the passivating agent comprises a compound selected from the group consisting 1,2,4-triazole (TAZ), benzotriazole, tolyltriazole, 5-phenyl-benzotriazole, 5-nitro-benzotriazole, 3-amino-5-mercapto-1,2,4-triazole, 1-amino-1,2,4-triazole, hydroxybenzotriazole, 2-(5-amino-pentyl)-benzotriazole, 1-amino-1,2,3-triazole, 1-amino-5-methyl-1,2,3-triazole, 3-amino-1,2,4-triazole, 3-mercapto-1,2,4-triazole, 3-isopropyl-1,2,4-triazole, 5-phenylthiol-benzotriazole, halo-benzotriazoles (halo=F, Cl, Br or I), naphthotriazole, 2-mercaptobenzimidazole (MBI), 2-mercaptobenzothiazole, 4-methyl-2-phenylimidazole, 2-mercaptothiazoline, 5-aminotetrazole, 5-aminotetrazole monohydrate, 5-amino-1,3,4-thiadiazole-2-thiol, 2,4-diamino-6-methyl-1,3,5-triazine, thiazole, triazine, methyltetrazole, 1,3-dimethyl-2-imidazolidinone, 1,5-pentamethylenetetrazole, 1-phenyl-5-mercaptotetrazole, diaminomethyltriazine, imidazoline thione, mercaptobenzimidazole, 4-methyl-4H-1,2,4-triazole-3-thiol, 5-amino-1,3,4-thiadiazole-2-thiol, benzothiazole, tritolyl phosphate, imidazole, indiazole, urea and thiourea compounds, oxalic acid, malonic acid, succinic acid, nitrilotriacetic acids, iminodiacetic acids, and derivatives and combinations thereof;
wherein the barrier layer removal enhancer comprises a compound selected from the group consisting of phthalic acid, salicylic acid, benzoic acid, and other aromatic carboxylic acids;
wherein the selectivity additive comprises a compound selected from the group consisting of poly(acrylic acid), anionic surfactants, and other polyelectrolytes; and
wherein the solvent comprises a compound selected from the group consisting of water, methanol, ethanol, propanol, butanol, ethylene glycol, propylene glycol, glycerin, and combinations thereof.

6. The CMP slurry composition of claim 1, comprising component (I), wherein the at least one oxidizing agent selected from the group consisting of hydrogen peroxide, ferric nitrate, potassium iodate, potassium permanganate, nitric acid, ammonium chlorite, ammonium chlorate, ammonium iodate, ammonium perborate, ammonium perchlorate, ammonium periodate, tetramethylammonium chlorite, tetramethylammonium chlorate, tetramethylammonium iodate, tetramethylammonium perborate, tetramethylammonium perchlorate, tetramethylammonium periodate, 4-methylmorpholine N-oxide, pyridine-N-oxide, urea hydrogen peroxide, and mixtures of two or more of such components;
wherein the abrasive comprises an acid-stable abrasive species selected from the group consisting of silica, acid-stable silica, alumina, silicon carbide, silicon nitride, iron oxide, ceria, zirconium oxide, tin oxide, titanium dioxide, organic polymer particles, epoxies, urethanes, polyesters, polyamides, polycarbonates, polyolefins, polyvinylchloride, polystyrenes, polyolefins, (meth)acrylics, alumina-coated colloidal silica and mixtures of two or more of such components;
wherein the passivating agent comprises a compound selected from the group consisting 1,2,4-triazole 1 (TAZ), benzotriazole, tolyltriazole, 5-phenyl-benzotriazole, 5-nitro-benzotriazole, 3-amino-5-mercapto-1,2,4-triazole, 1-amino-1,2,4-triazole, hydroxybenzotriazole, 2-(5-amino-pentyl)-benzotriazole, 1-amino-1,2,3-triazole, 1-amino-5-methyl-1,2,3-triazole, 3-amino-1,2,4-triazole, 3-mercapto-1,2,4-triazole, 3-isopropyl-1,2,4-triazole, 5-phenylthiol-benzotriazole, halo-benzotriazoles (halo=F, Cl, Br or I), naphthotriazole, 2-mercaptobenzimidazole (MBI), 2-mercaptobenzothiazole, 4-methyl-2-phenylimidazole, 2-mercaptothiazoline, 5-aminotetrazole, 5-aminotetrazole monohydrate, 5-amino-1,3,4-thiadiazole-2-thiol, 2,4-diamino-6-methyl-1,3,5-triazine, thiazole, triazine, methyltetrazole, 1,3-dimethyl-2-imidazolidinone, 1,5-pentamethylenetetrazole, 1-phenyl-5-mercaptotetrazole, diaminomethyltriazine, imidazoline thione, mercaptobenzimidazole, 4-methyl-4H-1,2,4-triazole-3-thiol, 5-amino-1,3,4-thiadiazole-2-thiol, benzothiazole, tritolyl phosphate, imidazole, indiazole, urea and thiourea compounds, oxalic acid, malonic acid, succinic acid, nitrilotriacetic acids, iminodiacetic acids, and derivatives and combinations thereof;
wherein the solvent comprises a compound selected from the group consisting of water, methanol, ethanol, propanol, butanol, ethylene glycol, propylene glycol, glycerin, and combinations thereof; and
wherein the at least one chelating agent comprises glycine, alanine, citric acid, acetic acid, maleic acid, oxalic acid, malonic acid, phthalic acid, succinic acid, nitrilotriacetic acid, iminodiacetic acid, ethylenediamine, CDTA, EDTA, and combinations thereof.

7. The CMP slurry composition of claim 1, wherein the acid-stable abrasive has a zeta potential less than about −30 mV at pH in a range of from about 4 to about 8.

8. The CMP slurry composition of claim 1, wherein the acid-stable abrasive is surface modified with a species selected from the group consisting of Fe³⁺, Ca²⁺, Ba²⁺, Co²⁺, cetyl trimethyl ammonium bromide, and combinations thereof.

9. The CMP slurry composition of claim 8, wherein the acid-stable abrasive has a zeta potential greater than about 20 mV at pH in a range of from about 2.9 to about 4.0.

10. The CMP slurry composition of claim 1, wherein the acid-stable abrasive has a average particulate diameter in a range from about 10 nm to about 1000 nm.

11. The CMP slurry composition of claim 1, wherein the acid-stable abrasive has a average particulate diameter in a range from about 20 nm to about 120 nm.

12. The CMP slurry composition of claim 1, comprising component (I), consisting essentially of hydrogen peroxide, 1,2,4-triazole, glycine, acid-stabilized silica, at least one pH adjustment agent, and water.

13. (canceled)

14. The CMP slurry composition of claim 1, comprising component (I), wherein the removal rate of copper that is greater than the removal rate of barrier layer and dielectric materials using said CMP slurry composition.

15. The CMP slurry composition of claim 1, comprising component (II), wherein the removal rate of barrier layer and dielectric materials is greater than or approximately equal to the removal rate of copper using said CMP slurry composition.

16. (canceled)

17. The CMP slurry composition of claim 1, comprising component (II), wherein the CMP slurry composition comprises acid-stable silica, 1,2,4-triazole, hydrogen peroxide, phthalic acid and poly(acrylic acid) (PAA) in an aqueous solution.

18. (canceled)

19. A method of polishing a wafer substrate having copper and barrier layer material deposited thereon at a platen, said method comprising:
contacting the microelectronic device substrate having copper thereon on the platen for sufficient time and under first chemical mechanical polishing (CMP) conditions with a first CMP slurry composition to substantially remove copper from the microelectronic device substrate and expose barrier layer material, wherein the first CMP slurry composition comprises at least one oxidizing agent, at least one passivating agent, at least one chelating agent, at least one solvent, and at least one acid-stable abrasive; and
contacting the microelectronic device substrate having barrier layer material thereon on the same platen for sufficient time and under second CMP conditions with a second CMP slurry composition to substantially remove barrier layer material from the microelectronic device substrate, wherein the second CMP slurry composition comprises at least one passivating agent, at least one barrier layer removal enhancer, at least one selectivity additive, at least one solvent, at least one acid-stable abrasive, and optionally at least one oxidizing agent,
with the proviso that the first and second CMP slurry compositions are devoid of persulfate and phosphorous acid and/or a salt thereof.

20. (canceled)

21. The method of claim 19, wherein the ratio of copper to barrier layer material removal using the first CMP slurry composition is in a range from about 100:1 to about 10,000:1.

22. (canceled)

23. The method of claim 19, wherein the ratio of copper to tantalum selectivity and copper to dielectric selectivity using the second CMP slurry composition is in a range from about 10:1 to about 1:10.

24. The method of claim 19, further comprising a first rinse of the platen pad with solvent or pad cleaning solution for sufficient time under first rinsing conditions prior to contacting the barrier layer material with the second CMP slurry composition.

25. The method of claim 19, further comprising a second rinse of the platen pad with solvent or pad cleaning solution for sufficient time under second rinsing conditions subsequent to contacting the barrier layer material with the second CMP slurry composition.

26. (canceled)

27. The method of claim 19, wherein the abrasive of the first CMP slurry comprises an acid-stable abrasive species selected from the group consisting of silica, alumina, silicon carbide, silicon nitride, iron oxide, ceria, zirconium oxide, tin oxide, titanium dioxide, organic polymer particles, epoxies, urethanes, polyesters, polyamides, polycarbonates, polyolefins, polyvinylchloride, polystyrenes, polyolefins, (meth)acrylics, alumina-coated colloidal silica and mixtures of two or more of such components;
wherein the oxidizing agent of the first CMP slurry comprises a compound selected from the group consisting of hydrogen peroxide, ferric nitrate, potassium iodate, potassium permanganate, nitric acid, ammonium chlorite, ammonium chlorate, ammonium iodate, ammonium perborate, ammonium perchlorate, ammonium periodate, tetramethylammonium chlorite, tetramethylammonium chlorate, tetramethylammonium iodate, tetramethylammonium perborate, tetramethylammonium perchlorate, tetramethylammonium periodate, 4-methylmorpholine N-oxide, pyridine-N-oxide, urea hydrogen peroxide, and mixtures of two or more of such components;
wherein the chelating agent of the first CMP slurry comprises a compound selected from the group consisting of glycine, alanine, citric acid, acetic acid, maleic acid, oxalic acid, malonic acid, succinic acid, nitrilotriacetic acid, iminodiacetic acid, ethylenediamine, EDTA, and mixtures of two or more of such components;
wherein the passivating agent of the first CMP slurry comprises a compound selected from the group consisting of 1,2,4-triazole (TAZ), benzotriazole, tolyltriazole, 5-phenyl-benzotriazole, 5-nitro-benzotriazole, 3-amino-5-mercapto-1,2,4-triazole, 1-amino-1,2,4-triazole, hydroxybenzotriazole, 2-(5-amino-pentyl)-benzotriazole, 1-amino-1,2,3-triazole, 1-amino-5-methyl-1,2,3-triazole, 3-amino-1,2,4-triazole, 3-mercapto-1,2,4-triazole, 3-isopropyl-1,2,4-triazole, 5-phenylthiol-benzotriazole, halo-benzotriazoles (halo=F, Cl, Br or I), naphthotriazole, 2-mercaptobenzimidazole (MBI), 2-mercaptobenzothiazole, 4-methyl-2-phenylimidazole, 2-mercaptothiazoline, 5-aminotetrazole, 5-aminotetrazole monohydrate, 5-amino-1,3,4-thiadiazole-2-thiol, 2,4-diamino-6-methyl-1,3,5-triazine, thiazole, triazine, methyltetrazole, 1,3-dimethyl-2-imidazolidinone, 1,5-pentamethylenetetrazole, 1-phenyl-5-mercaptotetrazole, diaminomethyltriazine, imidazoline thione, mercaptobenzimidazole, 4-methyl-4H-1,2,4-triazole-3-thiol, 5-amino-1,3,4-thiadiazole-2-thiol, benzothiazole, tritolyl phosphate, imidazole, indiazole, urea and thiourea compounds, oxalic acid, malonic acid, succinic acid, nitrilotriacetic acids, iminodiacetic acids, and derivatives and combinations thereof; and
wherein the solvent of the first CMP slurry comprises a compound selected from the group consisting of water, methanol, ethanol, propanol, butanol, ethylene glycol, propylene glycol, glycerin, and combinations thereof.

28. (canceled)

29. (canceled)

30. The method of claim 19, wherein the abrasive of the second CMP slurry comprises an acid-stable abrasive species selected from the group consisting of silica, acid-stable silica, alumina, silicon carbide, silicon nitride, iron oxide, ceria, zirconium oxide, tin oxide, titanium dioxide, organic polymer particles, epoxies, urethanes, polyesters, polyamides, polycarbonates, polyolefins, polyvinylchloride, polystyrenes, polyolefins, (meth)acrylics, alumina-coated colloidal silica and mixtures of two or more of such components;
wherein the passivating agent of the second CMP slurry comprises a compound selected from the group consisting 1,2,4-triazole (TAZ), benzotriazole, tolyltriazole, 5-phenyl-benzotriazole, 5-nitro-benzotriazole, 3-amino-5-mercapto-1,2,4-triazole, 1-amino-1,2,4-triazole, hydroxybenzotriazole, 2-(5-amino-pentyl)-benzotriazole, 1-amino-1,2,3-triazole, 1-amino-5-methyl-1,2,3-triazole, 3-amino-1,2,4-triazole, 3-mercapto-1,2,4-triazole, 3-isopropyl-1,2,4-triazole, 5-phenylthiol-benzotriazole, halo-benzotriazoles (halo=F, Cl, Br or I), naphthotriazole, 2-mercaptobenzimidazole (MBI), 2-mercaptobenzothiazole, 4-methyl-2-phenylimidazole, 2-mercaptothiazoline, 5-aminotetrazole, 5-aminotetrazole monohydrate, 5-amino-1,3,4-thiadiazole-2-thiol, 2,4-diamino-6-methyl-1,3,5-triazine, thiazole, triazine, methyltetrazole, 1,3-dimethyl-2-imidazolidinone, 1,5-pentamethylenetetrazole, 1-phenyl-5-mercaptotetrazole, diaminomethyltriazine, imidazoline thione, mercaptobenzimidazole, 4-methyl-4H-1,2,4-triazole-3-thiol, 5-amino-1,3,4-thiadiazole-2-thiol, benzothiazole, tritolyl phosphate, imidazole, indiazole, urea and thiourea compounds, oxalic acid, malonic acid, succinic acid, nitrilotriacetic acids, iminodiacetic acids, and derivatives and combinations thereof;
wherein the barrier layer removal enhancer of the second CMP slurry comprises a compound selected from the group consisting of phthalic acid, salicylic acid, benzoic acid, and other aromatic carboxylic acids;
wherein the selectivity additive of the second CMP slurry comprises a compound selected from the group consisting of poly(acrylic acid), anionic surfactants, and other polyelectrolytes; and
wherein the solvent of the second CMP slurry comprises a compound selected from the group consisting of water, methanol, ethanol, propanol, butanol, ethylene glycol, propylene glycol, glycerin, and combinations thereof.

31. (canceled)

32. The method of claim 31, wherein the concentration of hydrogen peroxide in the first CMP slurry is greater than the concentration of hydrogen peroxide in the second CMP slurry.

33. (canceled)

34. A kit comprising, in one or more containers, Step I CMP slurry composition reagents, wherein the Step I CMP slurry composition comprises at least one passivating agent, at least one oxidizing agent, at least one chelating agent, at least one solvent, at least one acid-stable abrasive, and optionally at least one pH adjustment agent, and wherein one or more additional components suitable for combination with the Step I CMP slurry to form a Step II CMP slurry are optionally included in one or more containers, wherein the one or more additional components are selected from the group consisting of at least one barrier layer removal enhancer, at least one selectivity enhancer, and combinations thereof.

35. (canceled)
